(19) United States
(12) Patent Application Publication
(10) Pub. No.: US 2026/0346381 A1
(43) Pub. Date: Nov. 5, 2026

(54) Joining Method, Method of Manufacturing Semiconductor Device, and Semiconductor Device

(71) Applicant: Mitsubishi Electric Corporation, Chiyoda-ku, Tokyo (JP)

(72) Inventor: Koji ASAMA, Chiyoda-ku, Tokyo (JP)

(73) Assignee: Mitsubishi Electric Corporation, Chiyoda-ku, Tokyo (JP)

(21) Appl. No.: 19/485,164

(22) PCT Filed: Mar. 14, 2024
(86) PCT No.: PCT/JP2024/010100

§ 371 Date: Nov. 17, 2025

(30) Foreign Application Priority Data
May 24, 2023 (JP) 2023-085438

(51) Int. Cl. B23K 35/28; B23K 1/00; B23K 101/40; B23K 103/10; C22C 21/00; H10W 40/00; H10W 40/47

(52) U.S. Cl. CPC B23K 35/286; B23K 1/0016; C22C 21/00; H10W 40/033; H10W 40/47; B23K 2101/40; B23K 2103/10

(57) ABSTRACT

The joining method includes preparing an aluminum member and a cladding material. The aluminum member has a first surface. The constituent material of the aluminum member is an aluminum alloy that contains magnesium. The cladding material has a second surface. The cladding material includes a core material and a brazing material disposed on the core material. The brazing material forms the second surface. The constituent material of the brazing material is an aluminum alloy that contains silicon. The joining method of the present disclosure further includes disposing the aluminum member and the cladding material in such a manner that the first surface and the second surface face each other, and melting the brazing material while the aluminum member is being pressed against the cladding material.

### TECHNICAL FIELD

The present disclosure relates to a joining method, a method of manufacturing a semiconductor device, and a semiconductor device.

### BACKGROUND ART

For example, Japanese Patent Laying-Open No. 59-48714 (PTL 1) describes a method of joining aluminum members. In the method of joining aluminum members described in PTL 1, firstly, a first aluminum member and a second aluminum member are prepared. Secondly, an insert material is disposed between the first aluminum member and the second aluminum member. The insert material is a hypereutectic aluminum alloy that contains silicon. Thirdly, the insert material is melted while the first aluminum member is being pressed against the second aluminum member (first pressing step). Fourthly, the melted insert material between the first aluminum member and the second aluminum member is extruded out by pressing the first aluminum member against the second aluminum member (second pressing step). According to the method of joining aluminum members described in PTL 1, the first aluminum alloy and the second aluminum alloy are joined to each other after the steps mentioned above.

### CITATION LIST

### Patent Literature

PTL 1: Japanese Patent Laying-Open No. 59-48714

### SUMMARY OF INVENTION

### Technical Problem

When joining aluminum members by brazing, it has been considered essential to use flux to remove an oxide film formed on a surface of the aluminum member. However, when the constituent material of the aluminum member is an aluminum alloy that contains magnesium, the function of flux is inhibited by magnesium, which makes brazing difficult even if flux is used. In the method of joining aluminum members described in PTL 1, it is difficult to manufacture the insert material, and the cost of the insert material is high. In addition, the method of joining aluminum members described in PTL 1 requires two pressing steps, which makes the method complicated. The present disclosure provides a joining method capable of brazing an aluminum member that contains magnesium without using flux or a special insert material.

### Solution to Problem

The joining method of the present disclosure includes preparing an aluminum member and a cladding material. The aluminum member has a first surface. The constituent material of the aluminum member is an aluminum alloy that contains magnesium. The cladding material has a second surface. The cladding material includes a core material and a brazing material disposed on the core material. The brazing material forms the second surface. The constituent material of the brazing material is an aluminum alloy that contains silicon. The joining method of the present disclosure further includes disposing the aluminum member and the cladding material in such a manner such that the first surface and the second surface face each other, and melting the brazing material while the aluminum member is being pressed against the cladding material.

### Advantageous Effects of Invention

According to the joining method of the present disclosure, it is possible to braze an aluminum member that contains magnesium without using flux or a special insert material.

### BRIEF DESCRIPTION OF DRAWINGS

FIG. 1 is a process diagram illustrating a joining method according to a first embodiment.

FIG. 2 is a cross-sectional view illustrating an aluminum member 10.

FIG. 3 is a cross-sectional view illustrating a cladding material 20.

FIG. 4 is a cross-sectional view illustrating a disposing step S2.

FIG. 5 is a cross-sectional view illustrating a joining step S3.

FIG. 6 is a cross-sectional view illustrating a joined body 100.

FIG. 7A is a first cross-sectional view illustrating a joining mechanism in the joining method according to the first embodiment.

FIG. 7B is a second cross-sectional view illustrating a joining mechanism in the joining method according to the first embodiment.

FIG. 8 is a cross-sectional view illustrating an aluminum member 10 to be used in the joining method according to a second embodiment.

FIG. 9A is a cross-sectional view illustrating an aluminum member 10 to be used in the joining method according to a third embodiment.

FIG. 9B is a cross-sectional view illustrating a cladding material 20 to be used in a modification of the joining method according to the third embodiment.

FIG. 10 is a cross-sectional view illustrating a disposing step S2 in the joining method according to a fourth embodiment.

FIG. 11A is a first cross-sectional view illustrating a joining mechanism in the joining method according to the fourth embodiment.

FIG. 11B is a second cross-sectional view illustrating a joining mechanism in the joining method according to the fourth embodiment.

FIG. 12 is an optical microscope image of a joining interface between aluminum member 10 and cladding material 20.

FIG. 13 is a schematic view illustrating a semiconductor device 200.

FIG. 14 is a perspective view illustrating a cladding material 20 constituting a fin unit 212.

FIG. 15A is a first schematic view illustrating a method of manufacturing the semiconductor device 200.

FIG. 15B is a second schematic view illustrating the method of manufacturing the semiconductor device 200.

FIG. 15C is a third schematic view illustrating the method of manufacturing the semiconductor device 200.

FIG. 16 is a cross-sectional view illustrating a fin unit 212 to be used in a semiconductor device 200A.

### DESCRIPTION OF EMBODIMENTS

Embodiments of the present disclosure will be described with reference to the drawings. In the following drawings, the same or corresponding components will be denoted by the same reference numerals, and the description thereof will not be repeated.

### First Embodiment

A Joining Method According to a First Embodiment will be Described.

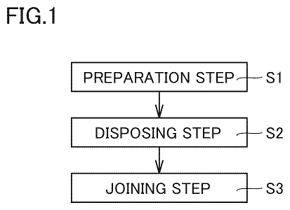

FIG. 1 is a process diagram illustrating a joining method according to a first embodiment. As illustrated in FIG. 1, the joining method according to the first embodiment includes a preparation step S1, a disposing step S2, and a joining step S3. The disposing step S2 is performed after the preparation step S1. The joining step S3 is performed after the disposing step S2.

### Configuration of Aluminum Member 10 and Cladding material 20

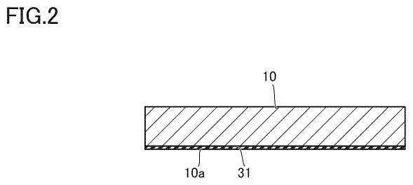

FIG. 2 is a cross-sectional view illustrating an aluminum member 10. As illustrated in FIG. 2, aluminum member 10 has a first surface 10a. First surface 10a is, for example, an end surface of aluminum member 10 in the thickness direction. The constituent material of aluminum member 10 is an aluminum alloy that contains magnesium. The constituent material of aluminum member 10 may be an aluminum alloy that contains magnesium and silicon. Specific examples of the constituent material of aluminum member 10 include a 5000-series aluminum alloy and a 6000-series aluminum alloy. First surface 10a is covered with an oxide film 31.

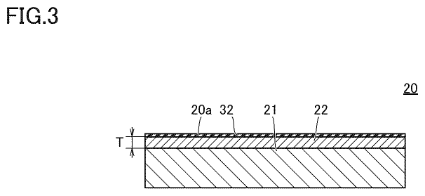

FIG. 3 is a cross-sectional view illustrating a cladding material 20. As illustrated in FIG. 3, cladding material 20 has a second surface 20a. Second surface 20a is, for example, an end surface of cladding material 20 in the thickness direction. Cladding material 20 includes a core material 21 and a brazing material 22. Brazing material 22 is disposed on core material 21. Brazing material 22 forms second surface 20a. Core material 21 and brazing material 22 are integrated by rolling. In the example illustrated in FIG. 3, brazing material 22 is disposed on only one of both end surfaces of core material 21, but brazing material 22 may be disposed on both end surfaces of core material 21. Second surface 20a is covered with an oxide film 32.

The constituent material of core material 21 is, for example, aluminum or an aluminum alloy. Specific examples of the constituent material of core material 21 include pure aluminum, a 1000-series aluminum alloy, a 3000-series aluminum alloy, and an aluminum alloy that contains manganese at 0.5% by mass or more and 2% by mass or less and the remainder being aluminum and inevitable impurities.

The constituent material of brazing material 22 is an aluminum alloy that contains silicon. The melting point of the constituent material of brazing material 22 is lower than the melting point of the constituent material of aluminum member 10 and the melting point of the constituent material of core material 21. If the concentration of silicon in brazing material 22 is too low, the melting point of brazing material 22 will not be sufficiently lowered. On the other hand, if the concentration of silicon in brazing material 22 is too high, the effect of lowering the melting point of brazing material 22 is small. If the concentration of silicon in brazing material 22 is too high, core material 21 becomes hard, which makes it difficult to manufacture cladding material 20. Thus, the concentration of silicon in brazing material 22 is preferably 4% by mass or more and 12% by mass or less. The constituent material of brazing material 22 may contain bismuth and/or lithium in addition to silicon. If the constituent material of brazing material 22 contains bismuth and/or lithium, the wettability of brazing material 22 can be improved.

The thickness of brazing material 22 is defined as thickness T. If thickness T is too small, the amount of brazing material 22 that melts and flows during the brazing may be insufficient to fill a gap between aluminum member 10 and core material 21, and thereby the gap may be partially remained between aluminum member 10 and core material 21. On the other hand, when thickness T is too large, the excessive brazing material 22 may erode core material 21. If thickness T is too large, the excess brazing material 22 may be pushed out from the side surfaces of aluminum member 10 and the side surfaces of core material 21. Thus, thickness T is preferably 0.01 mm or more and 0.1 mm or less.

Brazing material 22 pushed out from the side surfaces of aluminum member 10 and the side surfaces of core material 21 during the brazing may be removed by cutting or the like. The erosion of core material 21 may be prevented by lowering the concentration of silicon in brazing material 22 or by lowering the heating temperature during the brazing.

### Details of Joining Method According to First Embodiment

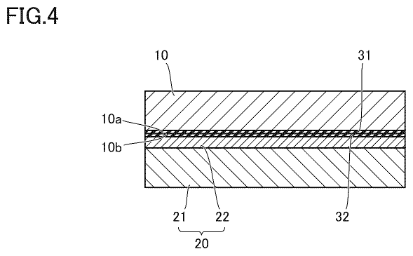

In the preparation step S1, aluminum member 10 and cladding material 20 are prepared. Aluminum member 10 and cladding material 20 are preferably cleaned before being subjected to the disposing step S2. Thus, oxide film 31 and oxide film 32 are removed (or the thickness of oxide film 31 and the thickness of oxide film 32 are reduced). FIG. 4 is a cross-sectional view illustrating the disposing step S2. As illustrated in FIG. 4, aluminum member 10 and cladding material 20 are disposed in such a manner that first surface 10a and second surface 20a face each other. At this time, no flux is supplied between first surface 10a and second surface 20a.

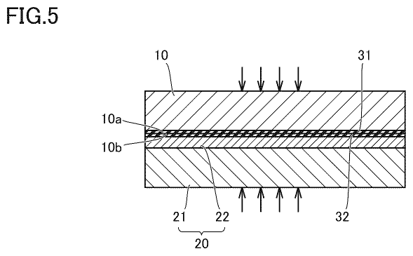

FIG. 5 is a cross-sectional view illustrating the joining step S3. As illustrated in FIG. 5, in the joining step S3, aluminum member 10 is pressed against cladding material 20. The pressing force to be applied is preferably 10 kPa or more, for example. The pressing is performed using, for example, a jig. In the joining step S3, aluminum member 10 and cladding material 20 are heated while the pressing is being performed. Thus, brazing material 22 is melted.

The heating temperature is equal to or higher than the solidus temperature of brazing material 22. If the heating temperature is lower than the solidus temperature of brazing material 22, brazing material 22 does not melt, and thereby the brazing cannot be performed. In order to increase the fluidity of melted brazing material 22 and promote the breaking of oxide film 32, the heating temperature is preferably equal to or higher than the liquidus temperature of brazing material 22. However, in order to prevent aluminum member 10 and core material 21 from melting, the heating temperature should be lower than the solidus temperature of aluminum member 10 and the solidus temperature of core material 21 (for example, lower than 630 °C). The heating is preferably terminated, for example, when the heating temperature reaches immediately above the liquidus temperature of brazing material 22. The heating temperature may be maintained for a certain period of time.

The joining step S3 is performed, for example, in an inert atmosphere under normal pressure. The inert gas may be, for example, nitrogen gas, argon gas, or the like. The concentration of oxygen in the atmosphere is preferably less than 500 ppm in order to inhibit the oxidation of aluminum member 10 and brazing material 22. After the heating is completed, melted brazing material 22 solidifies, and aluminum member 10 and cladding material 20 are joined to each other to form a joined body 100.

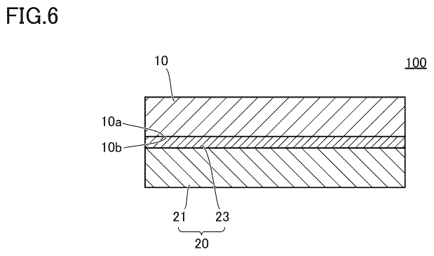

FIG. 6 is a cross-sectional view illustrating joined body 100. As illustrated in FIG. 6, in joined body 100, aluminum member 10 and core material 21 are joined to each other via a joining layer 23. Joining layer 23 is formed by cooling and solidifying melted brazing material 22. Joining layer 23 contains magnesium in addition to silicon. Magnesium in joining layer 23 is diffused from aluminum member 10. The amount of magnesium in joining layer 23 is trace. The concentration of magnesium in the entire joining layer 23 is, for example, less than 0.1% by mass.

### Effects of Joining Method According to First Embodiment

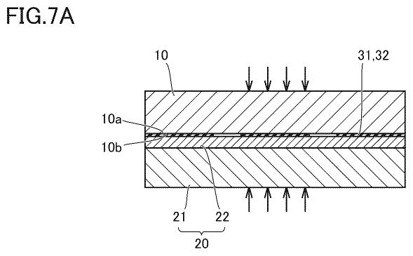

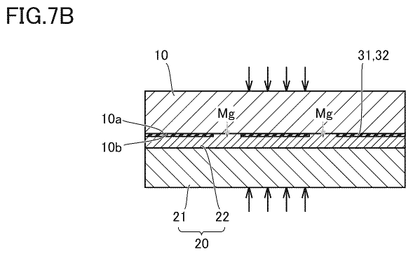

FIG. 7A is a first cross-sectional view illustrating a joining mechanism in the joining method according to the first embodiment. As illustrated in FIG. 7A, in the joining step S3, oxide film 31 and oxide film 32 are locally broken by pressure before brazing material 22 is melted. The portions of oxide film 31 and oxide film 32 which are locally broken are referred to as “broken portions”.

FIG. 7B is a second cross-sectional view illustrating the joining mechanism in the joining method according to the first embodiment. As illustrated in FIG. 7B, in the joining step S3, when the temperature is further increased, brazing material 22 is melted, melted brazing material 22 comes into contact with aluminum member 10 at the broken portions. Magnesium diffuses from the portions of aluminum member 10 in contact with melted brazing material 22 into melted brazing material 22. Since magnesium is active in melted brazing material 22 and has a stronger binding force with oxygen than aluminum, it deprives oxide film 31 and oxide film 32 of oxygen, which reduces or breaks oxide film 31 and oxide film 32. Therefore, in the joining method according to the first embodiment, since melted brazing material 22 and aluminum member 10 are in contact with each other with the oxide films removed therefrom, it is possible to achieve more satisfactory joining.

Generally in brazing an aluminum member, flux is supplied between the brazing material and the aluminum member to remove the oxide film formed on the surface of the aluminum member to achieve joining. However, if the constituent material of the aluminum member contains magnesium, since magnesium inhibits the removal of the oxide film by flux, it is difficult to achieve joining even if the flux is used. In contrast, in the joining method according to the first embodiment, since oxide film 31 and oxide film 32 are removed by the joining mechanism described above, it is possible to perform satisfactory brazing without using flux.

In the case where the constituent material of aluminum member 10 is an aluminum alloy that contains magnesium and silicon, the solidus temperature of the constituent material of aluminum member 10 is lower than that in the case where the constituent material of aluminum member 10 is an aluminum alloy that contains magnesium. Therefore, when the temperature is increased in the joining step S3, a part of the base material of aluminum member 10 melts, resulting in a solid-liquid coexistence state, and thereby oxide film 31 is further easily broken, which makes it possible to achieve more satisfactory joining.

### Second Embodiment

A joining method according to a second embodiment will be described. In the present embodiment, the differences from the joining method according to the first embodiment will be mainly described, and the description of the same contents will not be repeated.

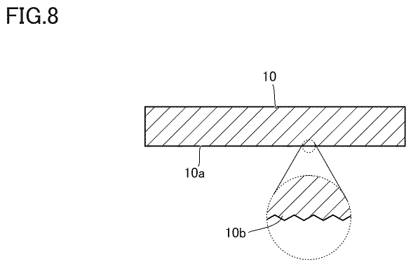

FIG. 8 is a cross-sectional view illustrating aluminum member 10 to be used in the joining method according to the second embodiment. In FIG. 8, oxide film 31 is not illustrated. As illustrated in FIG. 8, in the joining method according to the second embodiment, first surface 10a is formed with pimples and dimples. More specifically, first surface 10a is formed with protrusions 10b. The pimples and dimples (protrusions 10b) on first surface 10a are formed when, for example, a cutting process, a grinding process, a sand blasting process, or a wet blasting process is performed on first surface 10a.

As described above, in the joining step S3, aluminum member 10 is pressed against cladding material 20 in such a manner that first surface 10a and second surface 20a face each other. Thus, when first surface 10a is formed with protrusions 10b, since the contact area between the tip of each protrusion 10b and second surface 20a is extremely small, which causes stress concentration at each contact point, and thereby oxide film 31 and oxide film 32 are easily broken at each contact point. Therefore, according to the joining method of the second embodiment, the contact between melted brazing material 22 and aluminum member 10 is further promoted, which makes it possible to achieve more satisfactory joining.

In the above description, it is described that first surface 10a is formed with pimples and dimples, but second surface 20a may be formed with pimples and dimples (second surface 20a may be formed with protrusions), or both first surface 10a and second surface 20a may be formed with pimples and dimples. The height of each pimple or dimple (the distance from the material surface to the apex of each protrusion) is, for example, 5 μm or more and less than the thickness of brazing material 22. For example, when the thickness of brazing material 22 is 20 μm, the height of each pimple or dimple is preferably less than 20 μm.

In the above description, it is described that each protrusion 10b has a triangular shape in a cross-sectional view, but the shape of each protrusion 10b is not limited as long as it can induce stress concentration. The shape of each protrusion 10b in a cross-sectional view may be, for example, an arc shape or a trapezoidal shape.

### Third Embodiment

A joining method according to a third embodiment will be described. In the present embodiment, the differences from the joining method according to the first embodiment will be mainly described, and the description of the same contents will not be repeated.

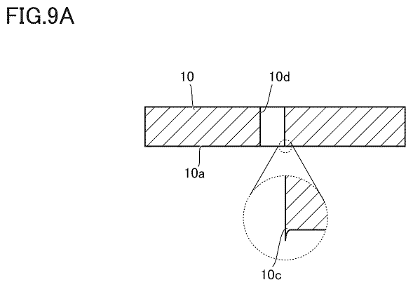

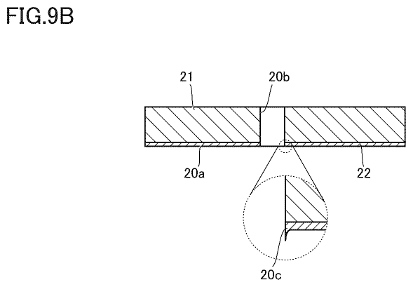

FIG. 9A is a cross-sectional view illustrating aluminum member 10 to be used in the joining method according to the third embodiment. In FIG. 9A, oxide film 31 is not illustrated. As illustrated in FIG. 9A, in the joining method according to the third embodiment, aluminum member 10 has a protrusion 10c. Protrusion 10c protrudes from first surface 10a. Protrusion 10c is, for example, a burr or a weld flash generated when a hole 10d is formed in aluminum member 10 by press working. In other words, protrusion 10c is located, for example, around hole 10d.

As described above, in the joining step S3, aluminum member 10 is pressed against cladding material 20 in such a manner that first surface 10a and second surface 20a face each other. Thus, if aluminum member 10 is formed with protrusion 10c, since the contact area between the tip of protrusion 10c and second surface 20a is extremely small, which causes stress concentration at the contact point, and thereby oxide film 31 and oxide film 32 are easily broken at the contact point. Therefore, according to the joining method of the third embodiment, the contact between melted brazing material 22 and aluminum member 10 is further promoted, which makes it possible to achieve more satisfactory joining.

FIG. 9B is a cross-sectional view illustrating a cladding material 20 to be used in a modification of the joining method according to the third embodiment. In FIG. 9B, oxide film 32 is not illustrated. In the above description, it is described that aluminum member 10 includes protrusion 10c, as illustrated in FIG. 9B, cladding material 20 may include a protrusion 20c protruding from second surface 20a. Protrusion 20c is located, for example, around a hole 20b. Protrusion 20c is a burr or a weld flash generated when hole 20b is formed by press working. Both aluminum member 10 and cladding material 20 may include a protrusion. As the number of holes 10d increases, the number of burrs or weld flashes increase, which is advantageous for joining.

### Fourth Embodiment

A joining method according to a fourth embodiment will be described. In the present embodiment, the differences from the joining method according to the first embodiment will be mainly described, and the description of the same contents will not be repeated.

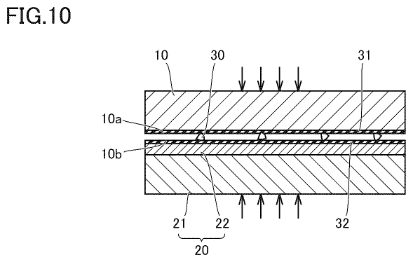

FIG. 10 is a cross-sectional view illustrating a disposing step S2 in the joining method according to a fourth embodiment. As illustrated in FIG. 10, in the joining method according to the fourth embodiment, aluminum member 10 and cladding material 20 are disposed in such a manner that first surface 10a and second surface 20a face each other with silicon particles 30 interposed therebetween.

Silicon particles 30 may be mixed with, for example, an organic solvent to form a paste, and then disposed between aluminum member 10 and cladding material 20. The purity of silicon particles 30 (the content ratio of silicon in silicon particles 30) is preferably 99% by mass or more. The particle size of silicon particles 30 is preferably smaller than thickness T. Silicon particles 30 preferably have an angular shape.

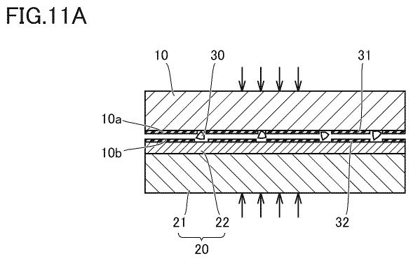

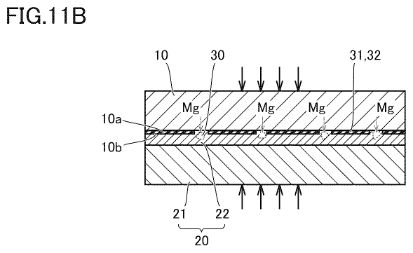

As described above, in the joining step S3, aluminum member 10 is pressed against cladding material 20. FIG. 11A is a first cross-sectional view illustrating a joining mechanism in the joining method according to the fourth embodiment. As illustrated in FIG. 11A, in the joining method according to the fourth embodiment, silicon particles 30 are interposed between aluminum member 10 and cladding material 20. Since the contact area between silicon particles 30 and aluminum member 10 and the contact area between silicon particles 30 and cladding material 20 are small, stress concentration is likely to occur at the contact points. This stress concentration promotes the breaking of oxide film 31 and oxide film 32.

Therefore, according to the joining method of the fourth embodiment, the contact between melted brazing material 22 and aluminum member 10 is further promoted, which makes it possible to achieve more satisfactory joining. If silicon particles 30 have an angular shape, the above-described stress concentration is more likely to occur, which further promotes the breaking of oxide film 31 and oxide film 32.

FIG. 11B is a second cross-sectional view illustrating a joining mechanism in the joining method according to the fourth embodiment. Silicon has a high melting point (about 1400°C), but is easily dissolved in molten aluminum. Therefore, as illustrated in FIG. 11B, silicon particles 30 are dissolved into brazing material 22 when brought into contact with melted brazing material 22, and thereby are eliminated from the joining interface. Therefore, even if silicon particles 30 are interposed between aluminum member 10 and cladding material 20, they do not adversely affect the joining process. When the particle size of silicon particles 30 is smaller than thickness T, silicon particles 30 are easily dissolved in melted brazing material 22, and silicon particles 30 can be more reliably eliminated from the joining interface.

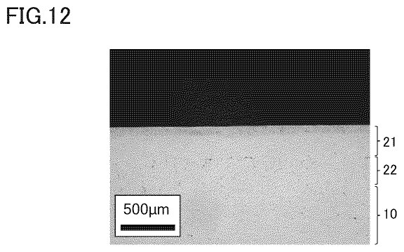

FIG. 12 is an optical microscope image of the joining interface between aluminum member 10 and cladding material 20. In the sample provided for taking the cross-sectional image of FIG. 12, the thickness of aluminum member 10 was 2 mm, and the constituent material of aluminum member 10 was A6063. In this sample, the thickness of cladding material 20 was 0.3 mm, the thickness of brazing material 22 was 0.021 mm, and the cladding ratio of cladding material 20 was 7.5 percent. In this sample, the constituent material of core material 21 was A3003, and the constituent material of brazing material 22 was an aluminum alloy that contains silicon at 7% by mass.

In this sample, silicon particles 30 were mixed with ethanol and supplied as a paste between aluminum member 10 and cladding material 20, the particle size of silicon particles 30 was 5 μm, the purity of silicon particles 30 was 99.9% by mass, and the application amount of the paste was 7.5g/m². In this sample, the pressing in the joining step S3 was performed using a pressing jig, and the pressing force was set to 100 kPa. In this sample, the heating in the joining step S3 was performed at 620 °C in a nitrogen atmosphere. Prior to the observation with an optical microscope, the sample was cut at the center, and the cross section was polished and etched. As illustrated in FIG. 12, it can be seen that in this sample, cladding material 20 and aluminum member 10 are satisfactorily joined, and no silicon particles 30 remain at the joining interface.

### Fifth Embodiment

A joining method according to a fifth embodiment will be described. In the present embodiment, the differences from the joining method according to the first embodiment will be mainly described, and the description of the same contents will not be repeated.

In the joining method according to the fifth embodiment, the concentration of magnesium in brazing material 22 is less than 0.1% by mass. The expression that “the concentration of magnesium is less than 0.1% by mass” includes a case where magnesium is not contained in brazing material 22. As the concentration of magnesium in brazing material 22 increases, brazing material 22 becomes harder and more brittle. Therefore, by setting the concentration of magnesium in brazing material 22 to 0.1% by mass or less, it is possible to ensure the rolling property of cladding material 20.

### Sixth Embodiment

A method of manufacturing a semiconductor device according to a sixth embodiment will be described.

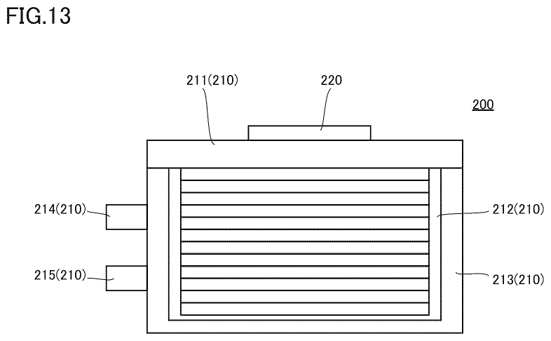

FIG. 13 is a schematic view illustrating a semiconductor device 200. As illustrated in FIG. 13, semiconductor device 200 includes a cooler 210 and a semiconductor chip 220. Cooler 210 includes a base 211, a fin unit 212, a jacket 213, a refrigerant inlet 214, and a refrigerant outlet 215.

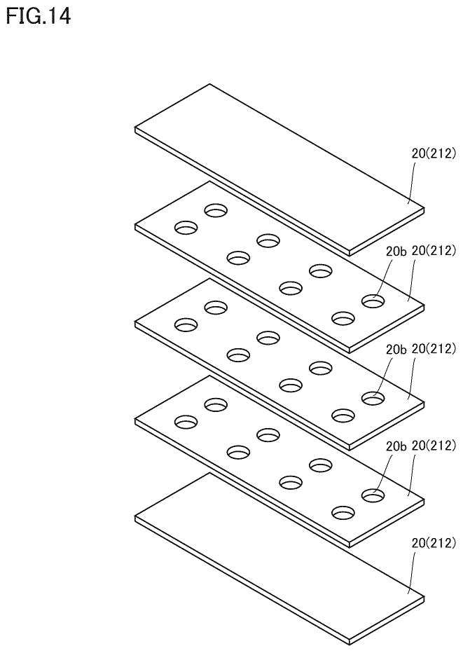

Base 211 is aluminum member 10. Fin unit 212 is cladding material 20. Base 211 is joined to fin unit 212. FIG. 14 is a perspective view illustrating multiple cladding materials 20 constituting fin unit 212. As illustrated in FIG. 14, a hole 20b is formed in each of cladding materials 20 constituting fin unit 212 as necessary. Hole 20b serves as a flow path for the refrigerant. The minimum width of hole 20b is, for example, about 0.2 mm. Hole 20b has, for example, an elliptical shape. In addition, it is preferable that each of cladding materials 20 is formed with a large number of holes 20b. The number of holes 20b is, for example, 50 or more for an area of 30 mm ×30 mm. The thickness of each of cladding materials 20 is, for example, 0.2 mm or more and 0.5 mm or less.

Jacket 213 has, for example, a box shape. Jacket 213 is attached to fin unit 212 so as to cover the outer surface of fin unit 212. Refrigerant inlet 214 and refrigerant outlet 215 are attached to jacket 213. The refrigerant flows into cooler 210 from refrigerant inlet 214, flows through a flow path formed inside cooler 210, and then is discharged through refrigerant outlet 215 to the outside of cooler 210.

Semiconductor chip 220 is disposed on base 211. Semiconductor chip 220 is soldered to base 211, for example. The soldering surface of base 211 may be subjected to plating so as to improve solder wettability. For example, copper plating, nickel plating, or the like is used for the plating. Semiconductor chip 220 may be joined to base 211 by, for example, sintering silver particles.

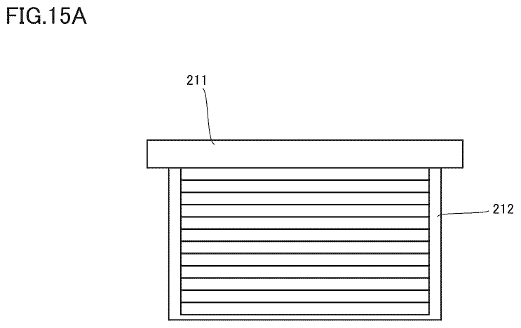

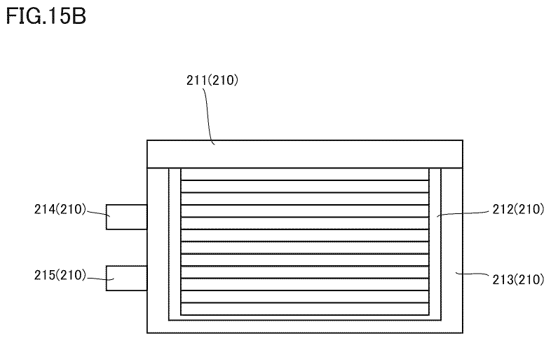

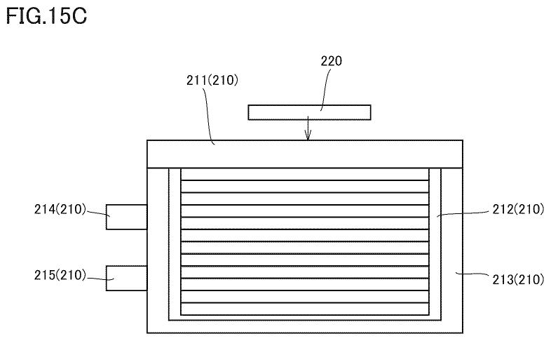

FIG. 15A is a first schematic view illustrating a method of manufacturing semiconductor device 200. Firstly, in the method of manufacturing semiconductor device 200, as illustrated in FIG. 15A, base 211 and fin unit 212 are stacked. Secondly, in the manufacturing method of semiconductor device 200, base 211 is brazed to fin unit 212 by the joining method according to any of the first, second, third, fourth, and fifth embodiments. Therefore, no flux is required to be supplied to the joining surface between base 211 and fin unit 212. The pressing in the joining method is performed, for example, by sandwiching base 211 and fin unit 212, which are stacked, between plate jigs and tightening the plate jigs with screws or the like.

FIG. 15B is a second schematic view illustrating the method of manufacturing semiconductor device 200. Thirdly, in the method of manufacturing semiconductor device 200, as illustrated in FIG. 15B, jacket 213 is attached to fin unit 212. Jacket 213 is attached to fin unit 212 by, for example, mechanical fastening, welding, brazing, solid-state welding, or the like. Fourthly, in the method of manufacturing semiconductor device 200, refrigerant inlet 214 and refrigerant outlet 215 are attached to jacket 213. Refrigerant inlet 214 and refrigerant outlet 215 are attached to jacket 213, for example, by brazing.

FIG. 15C is a third schematic view illustrating the method of manufacturing semiconductor device 200. Fifthly, in the method of manufacturing semiconductor device 200, semiconductor chip 220 is joined to base 211. Semiconductor chip 220 is joined to base 211 by soldering or by sintering silver particles, for example, as described above. Thus, the structure of semiconductor device 200 illustrated in FIG. 13 is formed.

### Seventh Embodiment

A method of manufacturing a semiconductor device according to a seventh embodiment will be described. In the present embodiment, the differences from the method of manufacturing the semiconductor device according to the sixth embodiment will be mainly described, and the description of the same contents will not be repeated.

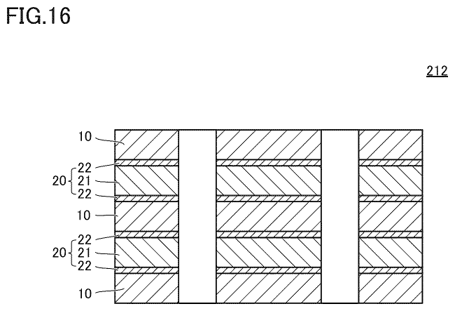

The semiconductor device according to the seventh embodiment is defined as a semiconductor device 200A. FIG. 16 is a cross-sectional view illustrating fin unit 212 to be used in semiconductor device 200A. As illustrated in FIG. 16, in semiconductor device 200A, fin unit 212 includes a plurality of aluminum members 10 and a plurality of cladding members 20.

As described above, the constituent material of aluminum member 10 is an aluminum alloy that contains magnesium or an aluminum alloy that contains magnesium and silicon. Cladding material 20 includes a brazing material 22 disposed on second surface 20a and a brazing material 22 disposed on the surface opposite to second surface 20a. In other words, cladding material 20 is a double-sided cladding material. The cladding ratio of cladding material 20 is, for example, 2 percent or more and 13 percent or less. In the present disclosure, the cladding ratio refers to such a value that is obtained by dividing the thickness of brazing material 22 disposed on one surface of cladding material 20 by the entire thickness of cladding material 20 and multiplying the result by 100. The thickness of brazing material 22 disposed on second surface 20a and the thickness of brazing material 22 disposed on the opposite surface of second surface 20a may be the same or different.

Fin unit 212 of semiconductor device 200A is obtained by alternately and repeatedly laminating aluminum member 10 and cladding material 20. However, the member that forms the outermost surface (the lowermost member or the uppermost member in FIG. 16) is aluminum member 10. This is because if the member that forms the outermost surface is cladding material 20, brazing material 22 may be joined to another member when melted.

When forming fin unit 212 of semiconductor device 200A, firstly, a hole is formed in aluminum member 10 and cladding material 20. This hole serves as a flow path through which the refrigerant flows. Secondly, aluminum member 10 and cladding material 20 are alternately laminated. At this time, no flux is applied between aluminum member 10 and cladding material 20. Thirdly, the laminated aluminum member 10 and cladding material 20 is heated under pressing so as to braze them with brazing material 22. As a result, fin unit 212 having a structure in which aluminum member 10, core material 21 and brazing material 22 are alternately arranged is formed. In the case where the aluminum alloy constituting aluminum member 10 contains silicon in addition to magnesium, a part of the base material of aluminum member 10 melts to be in a solid-liquid coexisting state when the temperature is increased for brazing, and thereby the oxide film is further easily broken, which makes it possible to achieve more satisfactory joining.

### Aspects

Aspects of the present disclosure will be summarized in the following.

### Aspect 1

A joining method comprising:
preparing an aluminum member and a cladding material,
wherein the aluminum member has a first surface,
the constituent material of the aluminum member is an aluminum alloy that contains magnesium,
the cladding material has a second surface,
the cladding material includes a core material and a brazing material disposed on the core material,
the brazing material forms the second surface,
the constituent material of the brazing material is an aluminum alloy that contains silicon,
the joining method further comprising:
disposing the aluminum member and the cladding material in such a manner that the first surface and the second surface face each other; and
melting the brazing material while the aluminum member is being pressed against the cladding material.

### Aspect 2

In the joining method according to aspect 1, wherein
the constituent material of the aluminum member is an aluminum alloy that contains magnesium and silicon.

### Aspect 3

In the joining method according to aspect 1 or aspect 2, wherein the first surface is formed with pimples and dimples.

### Aspect 4

In the joining method according to Aspect 1 or aspect 2, wherein the second surface is formed with pimples and dimples.

### Aspect 5

In the joining method according to aspect 1 or aspect 2, wherein the aluminum member has a first protrusion protruding from the first surface.

### Aspect 6

In the joining method according to aspect 1 or aspect 2, wherein the cladding material has a second protrusion protruding from the second surface.

### Aspect 7

In the joining method according to aspect 1 or aspect 2, wherein
the aluminum member and the cladding material are disposed in such a manner that the first surface and the second surface face each other with silicon particles interposed therebetween.

### Aspect 8

In the joining method according to any one of aspects 1 to 7, wherein
the concentration of magnesium in the brazing material is less than 0.1% by mass.

### Aspect 9

A method of manufacturing a semiconductor device comprising:
joining a base and a fin unit by the joining method according to any one of aspects 1 to 8,
wherein the base is the aluminum member, and the fin unit is the cladding material.

### Aspect 10

The method of manufacturing a semiconductor device according to aspect 9, further comprising:
attaching a jacket to the fin unit.

### Aspect 11

The method of manufacturing a semiconductor device according to aspect 9 or aspect 10, further comprising:
joining a semiconductor chip onto the base.

### Aspect 12

A semiconductor device comprising:
a cooler; and
a semiconductor chip joined to the cooler,
the cooler has a fin unit,
the fin unit includes a plurality of aluminum members and a plurality of cladding materials,
each of the plurality of aluminum members and each of the plurality of cladding materials are alternately laminated,
each of the plurality of cladding materials includes a core material and a brazing material disposed on one surface of the core material and the other surface of the core material opposite to the one surface,
the constituent material of the brazing material is an aluminum alloy that contains silicon, and
the constituent material of each of the plurality of aluminum members is an aluminum alloy that contains magnesium or an aluminum alloy that contains magnesium and silicon.

It should be understood that the embodiments disclosed herein are illustrative and non-restrictive in all respects. The scope of the present invention is defined by the terms of the claims rather than the description of the embodiments above, and is intended to include any modifications within the scope and meaning equivalent to the terms of the claims.

### REFERENCE SIGNS LIST

10: aluminum member; 10a: first surface; 10b: protrusion; 10c: protrusion; 10d: hole; 20: cladding material; 20a: second surface; 20b: hole; 20c: protrusion; 21: core material; 22: brazing material; 23: joining layer; 30: silicon particle; 31, 32: oxide film; 100: joined body; 200: semiconductor device; 210: cooler; 211: base; 212: fin unit; 213: jacket; 214: refrigerant inlet; 215: refrigerant outlet; 220: semiconductor chip; S1: preparation step; S2: disposing step; S3: joining step; T: thickness.

1. A joining method comprising:
preparing an aluminum member and a cladding material,
wherein the aluminum member has a first surface,
the constituent material of the aluminum member is an aluminum alloy that contains magnesium,
the cladding material has a second surface and a second protrusion protruding from the second surface,
the cladding material includes a core material and a brazing material disposed on the core material,
the brazing material forms the second surface,
the constituent material of the brazing material is an aluminum alloy that contains silicon, the joining method further comprising:
disposing the aluminum member and the cladding material in such a manner that the first surface and the second surface face each other; and
melting the brazing material while the aluminum member is being pressed against the cladding material.

2. The joining method according to claim 1, wherein
the constituent material of the aluminum member is an aluminum alloy that contains magnesium and silicon.

3. The joining method according to claim 1, wherein the first surface is formed with pimples and dimples.

4. The joining method according to claim 1, wherein the second surface is formed with pimples and dimples.

5. The joining method according to claim 1, wherein the aluminum member has a first protrusion protruding from the first surface.

6. (canceled)

7. The joining method according to claim 1, wherein
the aluminum member and the cladding material are disposed in such a manner that the first surface and the second surface face each other with silicon particles interposed therebetween.

8. The joining method according to claim 1, wherein the concentration of magnesium in the brazing material is less than 0.1% by mass.

9. A method of manufacturing a semiconductor device comprising:
joining a base and a fin unit by the joining method according to claim 1.
wherein the base is the aluminum member, and the fin unit is the cladding material.

10. The method of manufacturing a semiconductor device according to claim 9, further comprising:
attaching a jacket to the fin unit.

11. The method of manufacturing a semiconductor device according to claim 9, further comprising:
joining a semiconductor chip onto the base.

12. A semiconductor device comprising:
a cooler; and
a semiconductor chip joined to the cooler,
the cooler has a fin unit,
the fin unit includes a plurality of aluminum members and a plurality of cladding materials,
each of the plurality of aluminum members and each of the plurality of cladding materials are alternately laminated,
each of the plurality of cladding materials includes a core material and a brazing material disposed on one surface of the core material and the other surface of the core material opposite to the one surface,
the constituent material of the brazing material is an aluminum alloy that contains silicon,
the constituent material of each of the plurality of aluminum members is an aluminum alloy that contains magnesium or an aluminum alloy that contains magnesium and silicon, and
a hole is formed in the plurality of aluminum members and the plurality of cladding materials.

13. The semiconductor device according to claim 12, wherein
each of the plurality of aluminum members has a first surface facing each of the plurality of cladding members,
each of the plurality of aluminum members has a first protrusion protruding from the first surface, and
the first protrusion is a blur or a flash.

14. The semiconductor device according to claim 12, wherein
each of the plurality of cladding materials has a second surface facing each of the plurality of cladding members and has a second protrusion protruding from the second surface.

15. The semiconductor device according to claim 12, wherein the concentration of magnesium in the brazing material is less than 0.1% by mass.
